(19) United States
(12) Patent Application Publication
(10) Pub. No.: US 2006/0035442 A1
(43) Pub. Date: Feb. 16, 2006

(54) Layer arrangement and process for producing a layer arrangement

(75) Inventors: Gurkan Ilicali, Munich (DE); Erhard Landgraf, Munich (DE); Wolfgang Roesner, Ottobrunn (DE); Franz Hofmann, Munich (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/175,912

(22) Filed: Jul. 5, 2005

(30) Foreign Application Priority Data
Jul. 7, 2004 (DE) 10 2004 032 917.6

(51) Int. Cl. H01L 21/30

(52) U.S. Cl. 438/459; 438/977

(57) ABSTRACT

In a process for producing a layer arrangement, a first layer is formed with a thickness on a first side of a substrate, which thickness is greater than a minimum thickness for epitaxial growth, a second layer is epitaxially grown on the first layer, and a third layer is formed on the second layer. Furthermore, a handling wafer is bonded to the third layer, the substrate is removed from a second side, which is the opposite side to the first side of the substrate, and the first layer is thinned in subregions from the second side, so that after the thinning the thickness of the first layer is lower than a minimum thickness for epitaxial growth.

### CROSS-REFERENCE TO RELATED APPLICATION

This application claims priority to German Patent Application Serial No. 10 2004 032 917.6, which was filed on Jul. 7, 2004.

### FIELD OF THE INVENTION

The invention relates to a layer arrangement and to a process for producing a layer arrangement.

### BACKGROUND OF THE INVENTION

One of the challenges when producing a planar dual gate transistor and/or silicon-on-insulator metal oxide semiconductor transistor (SOI-MOS transistor) is to reduce parasitic resistances at the source region and the drain region. One way of partially reducing the parasitic resistances is to epitaxially form a layer of silicon on a very thin layer from which the channel region is also formed. An epitaxially grown silicon layer of this type is also referred to as raised silicon. The growth of the additional silicon layer means that there is sufficient material in the source region and drain region which are to be formed for subsequent siliciding and for contacts to be formed.

However, the epitaxial growth of a silicon layer requires a minimum thickness of the layer on which the silicon layer is epitaxially formed, i.e. of what is known as the seed layer. This minimum thickness is approximately 20 nm. At a thickness less than this minimum thickness, it is only possible to epitaxially form a uniform silicon layer with considerable difficulty.

However, as part of the further scaling of SOI planar metal oxide semiconductor field-effect transistors (MOSFETs), this minimum thickness of approximately 20 nm is leading to problems. In silicon technology, the performance of the individual component is adversely affected to a significant extent inter alia by short-channel effects. These undesirable short-channel effects include, for example: a weaker increase in the drain current with increasing gate voltage, a threshold voltage which is dependent on the working point and punch-through in source region and drain region.

It is known that these short-channel effects are attenuated if the thickness of the layer of the channel region does not exceed approximately a third to a quarter of the length of the channel region. Therefore, problems arise at a projected gate length of 10 nm to 30 nm for planar dual gate MOSFETs, since the thickness of the layer of the channel region is no longer sufficient for a raised silicon layer to be epitaxially grown thereon. In other words, for the projected gate length of 10 nm to 30 nm, the thickness of the channel region would have to be between approximately 2.5 nm and 10 nm, whereas for epitaxial growth of a silicon layer the thickness of the seed layer would have to be at least 20 nm. This contradiction is a serious problem in the production of a planar dual gate MOSFET.

EP 601 950 A2 describes a process for producing an SOI layer by means of wafer bonding. The process comprises the following steps: a first wafer is provided, having a silicon substrate of a first conductivity type and a diffusion layer of a second conductivity type formed on the silicon substrate, which diffusion layer has a first etching characteristic. Furthermore, a thin epitaxial layer of the second conductivity type is formed on the diffusion layer of the first wafer, which epitaxial layer has a second etching characteristic which differs from the first etching characteristic. Moreover, a thin oxide layer is formed on the thin epitaxial layer of the first wafer. Furthermore, a second wafer is provided, having a silicon substrate and a thin oxide layer formed on the silicon substrate. The first wafer and the second wafer are joined to one another by means of wafer bonding in such a way that the two thin oxide layers form a thick oxide layer. Then, the silicon substrate of the first wafer is removed. Furthermore, the diffusion layer of the first wafer is removed with the aid of a selective low-energy dry plasma etching process, so as to uncover the thin epitaxial layer beneath it. The ratio of the etching rates of diffusion layer and epitaxial layer is in this context such that the uncovered epitaxial layer is only slightly damaged by the plasma etching process.

U.S. 2003/0193070 A1 discloses a dual gate field-effect transistor which is produced using a Damascene-like process step. During the Damascene-like process step, side wall source/drain regions, oxide spacers and gate structures are formed in a trench which has previously been produced. The production process described in U.S. 2003/0193070 A1 forms a field-effect transistor with what is known as an inverse or inside-out geometry.

### SUMMARY OF THE INVENTION

A process for producing a layer arrangement including the the steps of forming a first layer with a thickness on a first side of a substrate, which thickness is greater than a minimum thickness for epitaxial growth of a second layer, epitaxially growing the second layer on the first layer, forming a third layer on the second layer, bonding a handling wafer to the third layer, removing the substrate from a second side, which is the opposite side to the first side, and thinning the first layer in subregions from the second side, so that after the thinning operation the thickness of the first layer is lower than the minimum thickness for epitaxial growth.

### BRIEF DESCRIPTION OF THE DRAWINGS

An exemplary embodiment of the invention is illustrated in the figures and described in more detail in the text which follows.

FIG. 1 shows a diagrammatic plan view illustrating a diagrammatic layout of a dual gate transistor;

FIG. 2 shows a diagrammatic cross-sectional view through a layer arrangement following substeps of a process in accordance with the exemplary embodiment for producing a dual gate transistor;

FIG. 3 shows a diagrammatic cross-sectional view through a layer arrangement of the exemplary embodiment following additional substeps for producing the dual gate transistor, which serve primarily to form a first gate region;

FIG. 4 shows a diagrammatic cross-sectional view through a layer arrangement of the exemplary embodiment following additional substeps for producing the dual gate transistor, which serve primarily to epitaxially form a silicon layer and to form a passivation layer;

FIG. 5 shows a diagrammatic cross-sectional view through a layer arrangement of the exemplary embodiment following additional substeps for producing the dual gate transistor, which serve primarily to carry out a wafer bonding step;

FIG. 6 shows a diagrammatic cross-sectional view through a layer arrangement of the exemplary embodiment following additional substeps for producing the dual gate transistor, which serve primarily to thin a channel region;

FIG. 7 shows a diagrammatic cross-sectional view through a layer arrangement of the exemplary embodiment following additional substeps for producing the dual gate transistor, which serve primarily to form an insulation;

FIG. 8 shows a diagrammatic cross-sectional view through a layer arrangement of the exemplary embodiment following additional substeps for producing the dual gate transistor, which serve primarily to form a second gate region; and

FIG. 9 shows a diagrammatic cross-sectional view through the completed dual gate transistor along the gates.

### DETAILED DESCRIPTION OF PREFERRED EMBODIMENTS OF THE INVENTION

The invention is based on the problem of providing a layer arrangement and a process for producing a layer arrangement in which the problems which are associated with epitaxial growth are overcome and known and simple process steps of silicon technology can be used in the production process.

In a process for producing a layer arrangement, a first layer is formed with a thickness on a first side of a substrate, which thickness is greater than a minimum thickness for epitaxial growth of a second layer, the second layer is epitaxially grown on the first layer, and a third layer is formed on the second layer. Furthermore, a handling wafer is bonded to the third layer, the substrate is removed from a second side, which is the opposite side to the first side, and the first layer is thinned in subregions from the second side, so that after the thinning operation the thickness of the first layer is lower than the minimum thickness for epitaxial growth.

A layer arrangement has a first layer with a layer thickness which is less than the minimum thickness for epitaxial growth, a second layer, which is epitaxially grown on the first layer, and a third layer. It is preferable for a transistor to include a layer arrangement of this type. It is particularly preferable for a dual gate transistor to include a layer arrangement of this type.

Clearly, one aspect of the invention can be considered to reside in the fact that, during the production of a layer arrangement which includes a thin first layer, i.e. a layer with a thickness which is less than a minimum layer thickness which allows epitaxial growth of a second layer, and on which a second layer has been epitaxially grown, the second layer is grown on a front surface of a thick first layer, i.e. a layer with a thickness which is greater than the minimum thickness which allows epitaxial growth of a second layer. Then, the thick first layer can be thinned from the back surface. As a result, it is possible to achieve layer thicknesses of the thinned first layer, which layer thicknesses do not allow epitaxial growth of a layer. Consequently, as a result of the thinning following a wafer bonding step, it is possible to achieve a layer thickness of the first layer which is sufficiently low, for example, to attenuate short-channel effects in a transistor.

It is possible in a simple way by means of the process according to the invention for producing a layer arrangement to obtain a layer arrangement with a second layer grown epitaxially on a thin first layer, the second layer being referred to as a raised layer.

It will be clear that the first side can be understood as meaning a first main side of the substrate, i.e. the top side of the substrate. The feature “from a second side” which is the opposite side to the first side can then obviously be understood as meaning from the opposite side from the first side, in the example “from below”, i.e. a second layer is epitaxially grown on the front side of a first layer, and then the first layer is thinned from the back side, so that thereafter a thin first layer and a second layer which has been grown epitaxially thereon are present. The minimum thickness for epitaxial growth is in this context also dependent on the individual process parameters, such as material, temperature, pressure, etc.

The possibility of back-surface thinning following a wafer bonding step opens up additional options for additional process steps, for the formation of layers, for transfer of layers by means of wafer bonding or for different combinations of materials, for example through the introduction of new materials or the bonding of two wafers made from different materials. In particular, it is possible to provide the first layer, which can evidently be regarded as a seed layer for the growth of the second layer, during growth of the second layer in a thickness which is sufficient for the epitaxy. Then, a wafer bonding step is carried out, thereby providing the option of thinning the first layer from the back surface.

In the context of the present application, a thin layer is preferably to be understood as meaning a layer with a thickness which does not allow epitaxial growth of a second layer or does so only with considerable difficulty, i.e. which is less than the minimum thickness for epitaxial growth, whereas a thick layer is preferably to be understood as meaning a layer with a thickness which is greater than the minimum thickness for epitaxial growth of a second layer and readily allows epitaxial growth.

The further configurations of the invention which are described in connection with the process according to the invention also apply to the layer arrangement according to the invention.

It is preferable for the thick first layer and the second layer to be formed from crystalline silicon.

Crystalline silicon is a suitable material for epitaxially forming layers in a layer arrangement. By way of example, both source/drain regions and a channel region of a transistor can be formed from crystalline silicon.

In a refinement, the thickness of the thinned first layer amounts to less than 50 nm, preferably less than 20 nm, more preferably between 2 nm and 20 nm and particularly preferably between 3 nm and 15 nm.

By means of the process according to the invention, it is possible to obtain epitaxially grown layers on seed layers which in a completed layer arrangement have a layer thickness which is less than the layer thickness required of a seed layer in conventional processes. It is therefore possible by means of the process according to the invention, for example, to achieve thicknesses of a channel region of a transistor which even for a gate length in the range from 10 nm to 30 nm are sufficiently small to substantially avoid short-channel effects.

It is preferable for a first layer sequence to be formed on the thinned first layer from the second side.

Forming a first layer sequence from the second side of the first layer makes it possible to form complex layer arrangements which, by way of example, may be complex integrated circuits. It is preferable for a first layer sequence of this type to be a gate region of a transistor.

It is particularly preferable for a fourth layer to be epitaxially grown on subregions of the thinned first layer from the second side.

In the subregions of the first layer on which the second layer has been epitaxially grown, it is possible to grow a fourth layer epitaxially from the second side. The process therefore allows double epitaxial growth of layers on one side. This obviously means once from the top side and once from the underside of the first layer. As a result, additional process steps and specially configured layer arrangements become possible. The fourth layer is preferably a crystalline silicon layer.

In a refinement, a transistor with a raised source region and with a raised drain region is formed by means of the layer arrangement.

The process is particularly suitable for producing a transistor with a raised source region and a raised drain region, which are preferably formed from the epitaxially grown second layer. To form the raised source region and the raised drain region, the second layer is preferably only selectively grown epitaxially on the first layer, i.e. the second layer is only grown in subregions of the first layer.

A dual gate transistor can be formed by means of the layer arrangement.

The process is particularly suitable for producing a dual gate transistor. By means of the wafer bonding and thinning of a first layer, it is possible first of all to form a first gate region and a raised source region and a raised drain region on a front surface of the first layer and then to form a second gate region and a raised source region and a raised drain region on the back surface of the first layer following the wafer bonding and thinning operations, with the result that it is possible to form a channel region of a low thickness, which thickness is suitable for alleviating short-channel effects.

It is preferable for a channel region of the transistor to be formed from the thinned first layer.

By means of the process according to the invention, it is possible to produce a thin channel region, so that short-channel effects can be reduced even at short gate lengths, and at the same time to epitaxially form a second layer on the channel region, preferably selectively.

It is particularly preferable for the raised source region and the raised drain region of the transistor to be formed from the second layer.

By the process described, it is possible to produce a transistor with a raised source region and a raised drain region in a particularly effective way.

In one exemplary embodiment, a second layer sequence is formed on subregions of the first layer prior to the thinning operation.

The second layer sequence may, for example, be a first gate region of a dual gate transistor which is formed in subregions of the first layer, which in turn can be used as channel region of the dual gate transistor. This exemplary embodiment is advantageous in particular in conjunction with the configuration in which the first layer sequence is formed and then represents a second gate region of the dual gate transistor.

The process according to the invention uses known process steps from silicon technology to create, in a simple and inexpensive way, a layer arrangement which includes a first thin layer, on which a second layer has been epitaxially grown, and a third layer.

The process according to the invention is suitable, for example, for the production of a planar dual gate transistor. The thin first layer can form the channel region of the dual gate transistor, and the second layer can be used to form a raised source region and a raised drain region. The third layer may in this context, by way of example, be a passivation layer which is formed on the source region and the drain region and to which a handling wafer is bonded.

Furthermore, the process according to the invention can also be used to produce single gate transistors.

Substeps of a process according to the invention for producing a planar dual gate transistor in accordance with an exemplary embodiment of the invention are explained in more detail with reference to the figures.

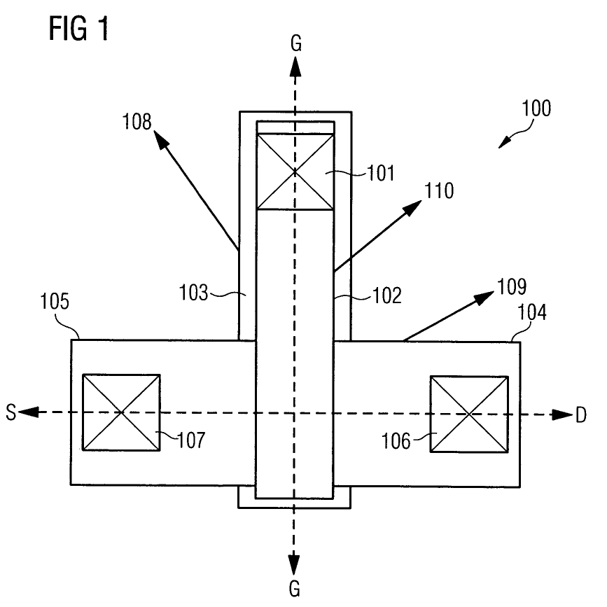

FIG. 1 shows a diagrammatic plan view showing a diagrammatic layout of a dual gate transistor 100. FIG. 1 serves primarily to illustrate the diagrammatic layout of the dual gate transistor 100 and to illustrate the different photolithographic regions which are defined by means of photolithographic masks in a process for producing the dual gate transistor 100 described below. FIG. 1 does not illustrate any encapsulation of the dual gate transistor 100 as a whole, in order to improve the clarity of the illustration.

The dual gate transistor 100 has a lower gate region, which in FIG. 1 is covered and is only indicated by a first contact-connection 101, preferably formed from a metal. Furthermore, the dual gate transistor 100 has an upper gate region 102, which according to the present exemplary embodiment is formed from polysilicon.

The dual gate transistor 100 shown in FIG. 1 also has an encapsulation 103, which electrically insulates the region of the upper gate region 102 and of the lower gate region with respect to the outside. The encapsulation 103 is preferably formed from silicon nitride (Si₃N₄) or silicon oxide (SiO₂).

Furthermore, the dual gate transistor 100 according to the invention has a drain region 104 and a source region 105, which are both preferably formed from silicon. A second contact-connection 106, which is preferably formed from metal, is illustrated in the drain region 104. A third contact-connection 107, which is preferably formed from a metal, is illustrated in the source region.

To facilitate understanding of the following figures and of the process for producing a planar dual gate transistor which is explained on the basis of the following figures, FIG. 1 also includes lines which form the section lines on which the cross-sectional views explained below are taken, and regions in which photolithographic steps are carried out during the process for producing a planar dual gate transistor.

Specifically, these are the section line G-G, which leads along the gate regions of the planar dual gate transistor, and the section line S-D, which leads along the source region and the drain region of the planar dual gate transistor. Furthermore, the contour line 108 indicates a photolithographic mask which is used in a first photolithographic step in which the region of the lower gate region of the planar dual gate transistor is defined. The contour line 109 denotes a photolithographic mask which is used in a second photolithographic step, in which the active region, i.e. the source region, the drain region and the channel region of the planar dual gate transistor, is defined. The contour line 110 denotes a photolithographic mask which is used in a third photolithographic step, in which the region of the upper gate region of the planar dual gate transistor is defined.

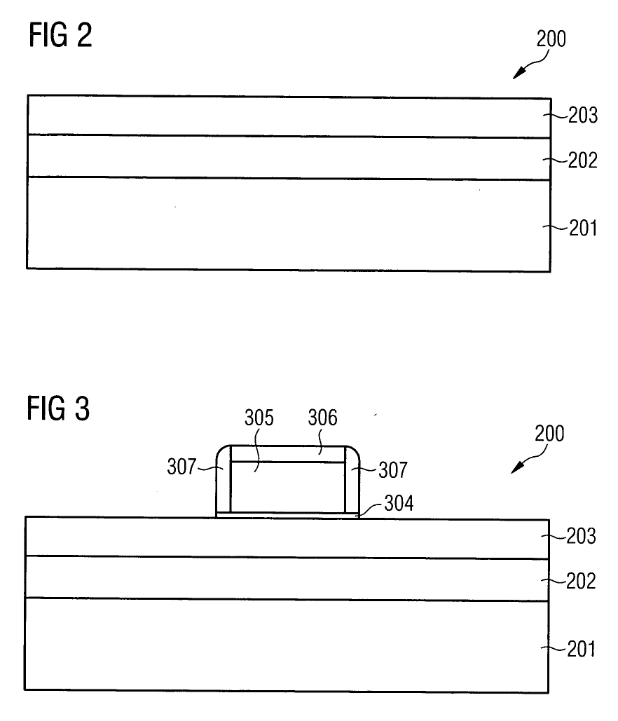

The text which follows describes a process for producing a planar dual gate transistor with reference to FIG. 2 to FIG. 9.

FIG. 2 diagrammatically depicts a layer arrangement 200 which corresponds to a silicon-on-insulator substrate (SOI substrate). The layer arrangement has a silicon support wafer 201, on which a first silicon oxide layer 202 has been formed as insulator layer. A first silicon layer 203 has been formed on the first silicon oxide layer 202. The thickness of the first silicon layer 203 permits a silicon layer to be formed epitaxially on it. The thickness of the first silicon layer 202 amounts to more than 10 nm, preferably more than 20 nm, particularly preferably between 20 nm and 50 nm. The first silicon layer is preferably formed from crystalline silicon.

Next, substeps of the process for producing the planar dual gate transistor which serve primarily to form a first gate region are described with reference to FIG. 3.

Starting from the layer arrangement 200 as shown in FIG. 2, the first silicon layer 203 is oxidized and patterned so as to form a first gate-insulating layer 304 of silicon oxide. Then, a first polysilicon layer 305 is formed on the gate-insulating layer 304 and is subsequently preferably doped.

As an alternative to polysilicon, it is also possible for another conductive material to be used for the layer 305. Then, a first silicon nitride layer 306 is formed. Furthermore, a second silicon oxide layer (not shown in FIG. 3), which is used as hard mask for a subsequent etching step, is formed. Subsequently, the lower gate region is formed from the first polysilicon layer 305, and subsequently part of the encapsulation of the lower gate region is formed from the first silicon nitride layer 306.

Then, a first photolithographic step is carried out. For this purpose, a photoresist is applied using a first mask, which corresponds to the region indicated by means of line 108 in FIG. 1, in order to act as a hard mask in the patterning of the second silicon oxide layer. Then, in a first etching step, the first silicon nitride layer 306 and the first polysilicon layer 305 are etched. The etch stop used in this operation may be the gate-insulating layer 304 of the first gate region, i.e. of the lower gate region. Then, the second silicon oxide layer, which was used as hard mask for the first etching step, is removed.

Thereafter, a second layer of silicon nitride 307 is formed, preferably by means of conformal deposition. Next, the third silicon nitride layer 307 is anisotropically etched in a second etching step, resulting in the formation of spacers 307 of silicon nitride. The gate-insulating layer 304 is used as etch stop layer in the second etching step. The spacers 307 of silicon nitride serve to encapsulate the lower gate region 305. Then, the gate-insulating layer 304 is etched in a third etching step, in which the encapsulation of the lower gate region, i.e. the spacers 307, can serve as a mask. The first silicon layer 203 can be used as an etch stop layer. As an alternative to using a hard mask of silicon oxide in the first etching step, it is also possible to carry out a photolithography step using a mask of photoresist.

The substeps described with reference to FIG. 3 form the lower gate region of the planar dual gate transistor and its encapsulation.

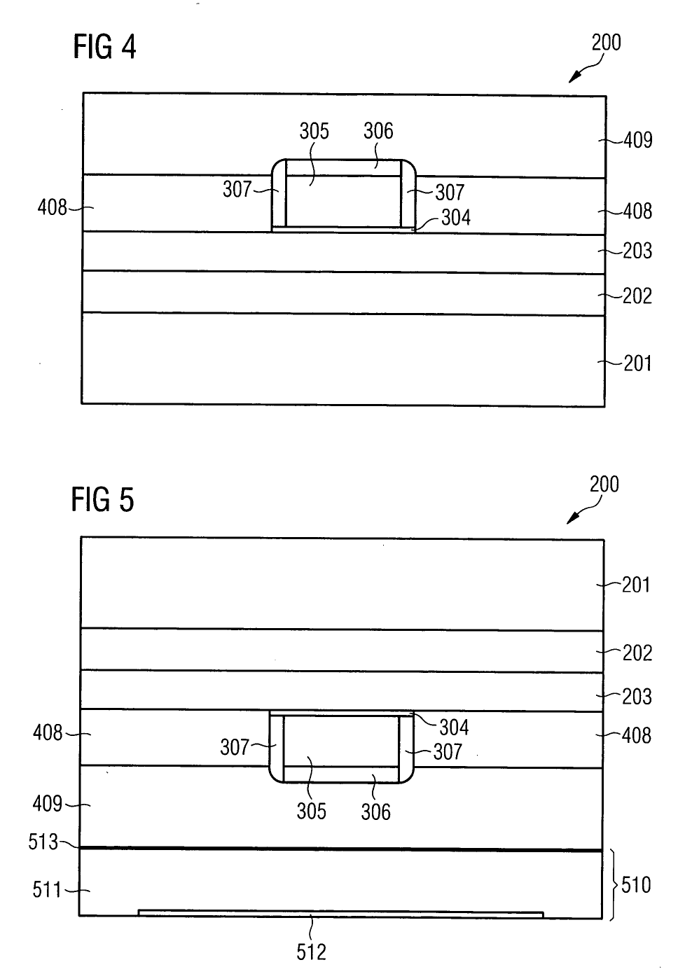

Next, substeps of the process for producing a planar dual gate transistor which serve primarily to epitaxially form a second silicon layer and to form a passivation layer are explained with reference to FIG. 4.

Starting from the layer arrangement which is illustrated in FIG. 3, a second silicon layer 408 is formed selectively by means of epitaxy on the first silicon layer 203, i.e. the second silicon layer 408 is grown on those regions of the first silicon layer 203 which have been uncovered by means of the third etching step. Since the first silicon layer 203 has been selected to be sufficiently thick, epitaxial growth of the second silicon layer 408 is possible in a simple way. Then, a thick third silicon oxide layer 409, which serves to passivate the layer arrangement 200 and is subsequently planarized, preferably by means of chemical mechanical polishing, is formed on the layer arrangement 200. The second silicon layer is preferably formed from crystalline silicon.

The substeps described with reference to FIG. 4 conclude the epitaxial growth of the second silicon layer 408 and the formation of the passivation layer 409.

Next, substeps of the process for producing a planar dual gate transistor which serve primarily for wafer bonding are explained with reference to FIG. 5.

Starting from the layer arrangement which is illustrated in FIG. 4, a handling wafer 510, which includes a thick fourth silicon oxide layer 511 and a third silicon layer 512, is bonded onto the planarized third silicon oxide layer 409 by means of the fourth silicon oxide layer 511. The handling wafer 510 clearly has the fourth silicon oxide layer 511 on its sides. The fourth silicon oxide layer 510 can preferably be formed by means of thermal oxidation of the third silicon layer 512 of the handling wafer 510. Furthermore, FIG. 5 diagrammatically depicts a bonding interface 513 which represents the surface at which the layer arrangement illustrated in FIG. 4 and the handling wafer are bonded to one another.

The third silicon oxide layer 409 of the layer arrangement shown in FIG. 4, after it has been planarized and prior to the wafer bonding, can be activated chemically or by means of plasma. After the wafer bonding step, the entire layer arrangement 200 is heat-treated. The layer arrangement is turned over for the subsequent substeps. Consequently, from FIG. 5 onward, the layer arrangement is illustrated turned over in the subsequent figures, which means that the top of FIG. 4 is the bottom of FIG. 5.

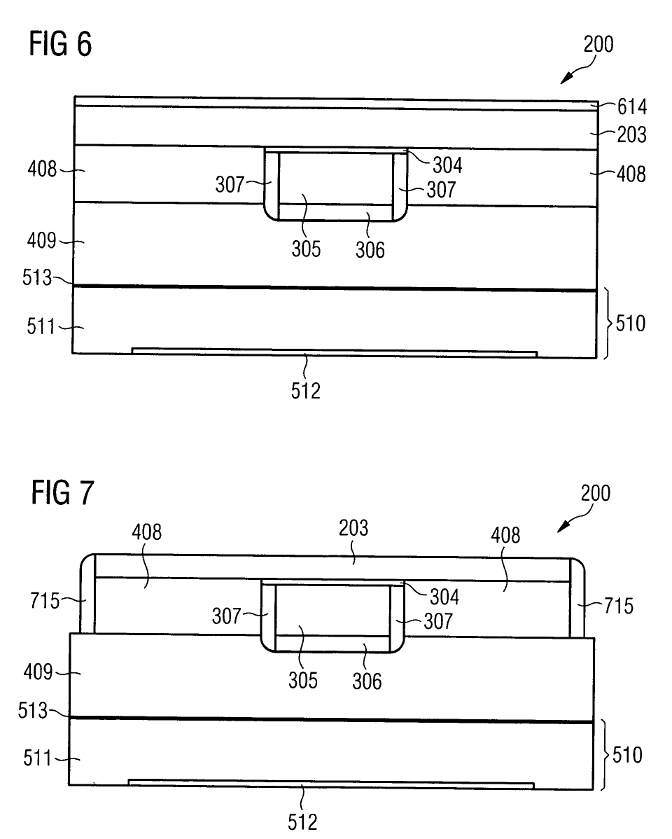

Next, substeps of the process for producing the planar dual gate transistor which serve primarily to thin the first silicon layer are explained with reference to FIG. 6.

Starting from the layer arrangement which is illustrated in FIG. 5, the silicon support wafer 201 is removed. This is preferably done by grinding or by what is known as the smart-cut process. Then, possible residues of the silicon support wafer 201 are selectively etched back by means of alkaline solutions in a fourth etching step. The etchback can be carried out, for example, by means of ethylenediamine pyrocatechol (EDP), tetramethylammonium hydroxide (TMAH), potassium hydroxide (KOH) or choline (2-hydroxyethyl trimethyl ammonium hydroxide). The etching solutions listed have a selectivity between silicon and silicon oxide. The first silicon oxide layer 202 of the SOI substrate is used as etching stop layer for the fourth etching step.

Then, the first silicon oxide layer 202 is removed in a selective fifth etching step. An etchant which is selective with respect to silicon is used for this purpose. The fifth etching step can be carried out, for example, by means of hydrogen fluoride (HF). The first silicon layer 203 can be used as etching stop layer in this step.

Then, the first silicon layer 203, from which the channel region of the dual gate transistor is subsequently formed, is thinned. It is preferable for the thinning of the first silicon layer 203 to be carried out by means of partial oxidation, resulting in the formation of a fifth silicon oxide layer 614. Then, the fifth silicon oxide layer 614 is removed by means of a sixth etching step. As an alternative to the oxidation and subsequent etchback, the thinning can also be carried out by means of chemical mechanical polishing.

The substeps described with reference to FIG. 6 conclude the removal of the silicon carrier wafer and the thinning of the first silicon layer; FIG. 6 illustrates the layer arrangement still with the fifth silicon oxide layer 614. The thinning of the first silicon layer 203, from which the channel region of the dual gate transistor is subsequently formed, ensures that the thickness of the channel region amounts to no more than a third to a quarter of the gate length, which allows the occurrence of short-channel effects to be reduced.

Next, substeps of the process for producing a planar dual gate transistor which serve primarily to insulate the source region and the drain region are explained with reference to FIG. 7.

Following the removal of the fifth silicon oxide layer 614 by means of selective etching, a second photolithographic step is carried out, by means of which the active region, i.e. the region in which the source region, the drain region and the channel region are subsequently formed, is defined. The mask used for the second photolithographic step is a mask which corresponds to the second contour line 109 in FIG. 1; in the second photolithographic step, a photoresist is exposed and developed. Then, the first silicon layer and the second silicon layer 409 are removed by means of a seventh etching step, in which the etching stop layer used is the third silicon oxide layer 409.

Then, a third silicon nitride layer 715 is formed on the layer arrangement 200. The formation of the third silicon nitride layer 715 is preferably carried out by means of conformal deposition. Then, the third silicon nitride layer 715 is etched by means of an eighth anisotropic etching step, resulting in the formation of spacers 715 of silicon nitride, which form an insulation for the first silicon layer 203 and the second silicon layer 409, i.e. for the source region and the drain region of the dual gate transistor.

The substeps described with reference to FIG. 7 conclude the formation of an insulation for the source region and the drain region.

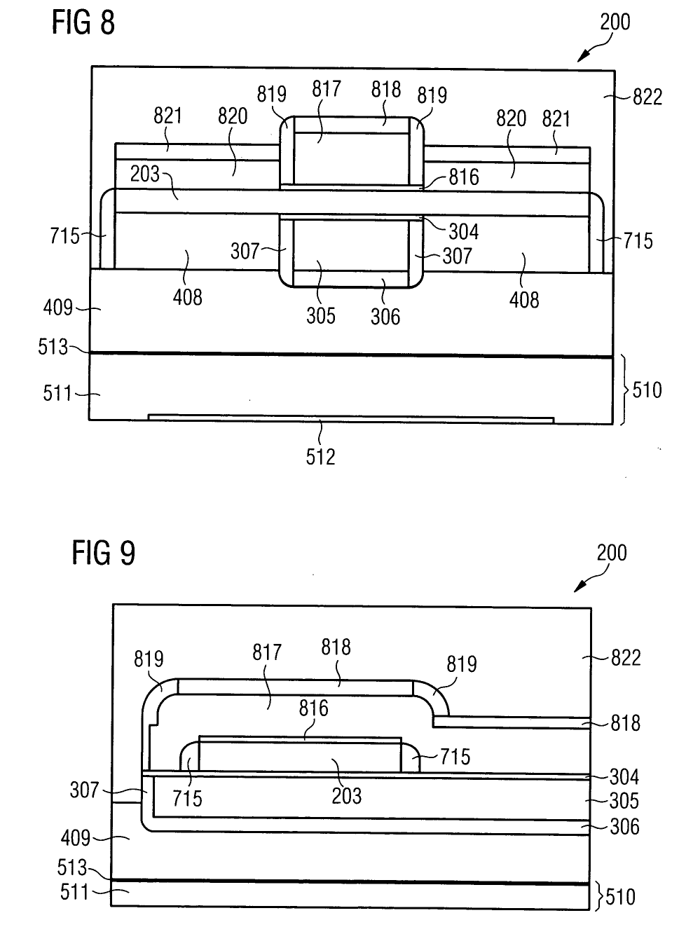

Next, substeps of the process for producing a planar dual gate transistor which serve primarily to form a second gate region are explained with reference to FIG. 8.

Starting from the layer arrangement 200 illustrated in FIG. 7, the first silicon layer 203 is oxidized, preferably thermally, resulting in the formation of a sixth silicon oxide layer 816. The sixth silicon oxide layer 816 subsequently forms a second gate-insulating layer, which serves as gate insulation for the second gate region with respect to the channel region of the planar dual gate transistor. Then, a second polysilicon layer 817, which is subsequently preferably doped and forms the second gate region, i.e. the upper gate region, of the planar dual gate transistor, is formed on the layer arrangement. Alternatively, the second gate region may also be formed by means of layer of a different conductive material rather than by means of a layer of polysilicon.

Then, a fourth silicon nitride layer 818 is formed. Furthermore, a seventh silicon oxide layer (not shown in FIG. 8), which is used as hard mask for a subsequent etching step, is formed. Subsequently, the upper gate region is formed from the second polysilicon layer 817 and subsequently part of the encapsulation of the upper gate region is formed from the fourth silicon nitride layer 818.

Then, a third photolithographic step is carried out. For this purpose, a photoresist is applied using a third mask, which corresponds to the region indicated by means of the line 110 in FIG. 1, in order to act as a hard mask for patterning the seventh silicon oxide layer. Next, in a ninth etching step, the fourth silicon nitride layer 818 and the second polysilicon layer 817 are etched. The etching stop used in this case may be the gate-insulating layer 816 of the second gate region, i.e. of the upper gate region.

Then, a fifth silicon nitride layer 819 is formed, this formation preferably being carried out by means of conformal deposition. Next, the fifth silicon nitride layer 819 is anisotropically etched in a tenth etching step, resulting in the formation of spacers 819 of silicon nitride. The silicon nitride spacers 819 serve to encapsulate the upper gate region 817. Then, the gate-insulating layer 816 of the upper gate region is etched in an eleventh etching step; in this step, the encapsulation of the upper gate region, i.e. the spacers 819, can be used as a mask. The etch stop layer used may be the first silicon layer 203. During the eleventh etching step, the seventh silicon oxide layer, which was used as a hard mask in the ninth etching step, is also removed.

Then, a fourth, preferably crystalline, silicon layer 820 is formed selectively by means of epitaxy on the first silicon layer 203, i.e. the fourth silicon layer 820 is grown on those regions of the first silicon layer 203 which have been uncovered by means of the eleventh etching step. The second epitaxial growth of a crystalline silicon layer on the first silicon layer 203 is also possible in a simple way. Although the etchback of the first silicon layer 203 reduced the thickness of the first silicon layer 203 to such an extent that the thickness of the channel region is low in the regions in which the fourth silicon layer 820 is formed during the second epitaxial growth, the effective thickness of the first silicon layer is increased by the second silicon layer 408. The formation of the fourth silicon layer 820 is optional depending on the application, i.e. it is not necessary for this layer to be formed for every application.

Then, the fourth silicon layer 820, i.e. the source region and the drain region of the dual gate transistor, is doped and activated. Thereafter, a metal layer which is used to silicide a surface region of the fourth silicon layer 820 is formed on the doped fourth silicon layer 820. The siliciding forms a silicide layer 821 which is used to reduce the contact resistance of the source region and of the drain region.

Then, a thick eighth silicon oxide layer 822, which serves to passivate the layer arrangement 200 and which is subsequently planarized, preferably by means of chemical mechanical polishing, is formed on the layer arrangement 200.

The substeps described with reference to FIG. 8 complete the body of the dual gate transistor. Finally, the dual gate transistor is contact-connected by means of conventional back end process steps, which are not described in more detail.

To provide a better understanding of the structure of the dual gate transistor which is produced by means of the described process of the exemplary embodiment, FIG. 9 additionally shows the layer arrangement shown in FIG. 8 in a cross-sectional view along the gate regions, i.e. on line G-G in FIG. 1.

FIG. 9 illustrates the handling wafer 510 with the fourth silicon oxide layer 511. The figure also indicates the bonding interface 513, on which the third silicon oxide layer 409 is arranged. The encapsulation of the lower gate region 305 is realized by means of the first silicon nitride layer 306 and the second silicon nitride layer 307, which forms the spacers or side wall layers. The lower gate region 305 is electrically decoupled from the channel region, i.e. the first silicon layer 203, by means of the first gate-insulating layer 304 of silicon oxide. Furthermore, the channel region 203 is electrically decoupled from the second gate region 817, i.e. the upper gate region, by means of the third silicon nitride layer 715 and the second gate-insulating layer 816, i.e. the sixth silicon oxide layer 816. The encapsulation of the upper gate region 817 is realized by means of the fourth silicon nitride layer 818 and the fifth silicon nitride layer 819, which forms the spacers 819. Furthermore, an eighth silicon oxide layer 822 has additionally been formed as a passivation for the dual gate transistor.

Examples of typical dimensions of a dual gate transistor produced by means of the described process with a gate length of approximately 45 nm and beyond this 45 nm may be in the range from 80 nm to 120 nm for the source/drain regions, in the range from 3 nm to 20 nm for the silicon layer of the channel region and in the range from 30 nm to 60 nm for the spacers of the gate.

To summarize, the invention relates to a process which can be used to produce a planar dual gate transistor and employs known, simple and inexpensive substeps of semiconductor technology. One aspect of the invention can be regarded as residing in the fact that a layer which has a sufficient thickness to allow epitaxial growth of a second layer on it is thinned from the back surface following a wafer bonding step. By means of the process according to the invention, it is possible to carry out the epitaxial growth of layers in a simple way.

The linking of the individual substeps in accordance with the invention produces a planar dual gate transistor in which the control action of two gate regions drastically reduces short-channel effects.

1-12. (canceled)

13. A process for producing a layer arrangement, comprising the steps of:
forming a first layer with a thickness on a first side of a substrate, which thickness is greater than a minimum thickness for epitaxial growth of a second layer;
epitaxially growing the second layer on the first layer;
forming a third layer on the second layer;
bonding a handling wafer to the third layer;
removing the substrate from a second side, which is the opposite side to the first side; and
thinning the first layer in subregions from the second side, so that after the thinning operation the thickness of the first layer is lower than a minimum thickness for epitaxial growth.

14. The process as claimed in claim 13, wherein the first layer and the second layer are formed from crystalline silicon.

15. The process as claimed in claim 13, wherein the thickness of the thinned first layer is less than 50 nm.

16. The process as claimed in claim 15, wherein the thickness of the thinned first layer is less than 20 nm.

17. The process as claimed in claim 16, wherein the thickness of the thinned first is between 2 nm and 20 nm.

18. A process for producing a dual gate transistor, comprising the steps of:
forming a first layer with a thickness on a first side of a substrate, which thickness is greater than a minimum thickness for epitaxial growth of a second layer;
epitaxially growing the second layer on the first layer;
forming a first gate region on a subregion of the second layer;
forming a third layer on the uncovered regions of the second layer and on the first gate region;
bonding a handling wafer to the third layer;
removing the substrate from a second side, which is the opposite side to the first side; and
thinning the first layer in subregions from the second side, so that after the thinning operation the thickness of the first layer is lower than a minimum thickness for epitaxial growth.

19. The process as claimed in claim 18, wherein the first layer and the second layer are formed from crystalline silicon.

20. The process as claimed in claims 18, wherein the thickness of the thinned first layer is less than 50 nm.

21. The process as claimed in claim 20, wherein the thickness of the thinned first layer is less than 20 nm.

22. The process as claimed in claim 21, wherein the thickness of the thinned first layer is between 2 nm and 20 nm.

23. The process as claimed in claim 18, further comprising the steps of:
forming a second gate region on an opposite side of the first layer from the first gate region; and
epitaxially growing a fourth layer laterally next to the second gate region on the thinned first layer from the second side.

24. The process as claimed in claim 18, further comprising the steps of:
forming a second gate region on an opposite side of the first layer from the first gate region; and
forming a raised source region and a raised drain region next to the first gate region and/or next to the second gate region.

25. A dual gate transistor comprising:
a first layer having a thickness that is lower than a minimum thickness for epitaxial growth;
a second layer formed on the first layer;
a first gate region formed on a subregion of the second layer;
a third layer formed on the uncovered regions of the second layer and on the first gate region; and
a handling wafer bonded to the third layer.

26. The arrangement as claimed in claim 25, wherein the first layer and the second layer are formed from crystalline silicon.

27. The arrangement as claimed in claims 25, wherein the thickness of the first layer is less than 50 nm.

28. The arrangement as claimed in claim 27, wherein the thickness of the first layer is less than 20 nm.

29. The arrangement as claimed in claim 28, wherein the thickness of the first layer is between 2 nm and 20 nm.

30. The arrangement as claimed in claim 25, further comprising:
a second gate region formed on an opposite side of the first layer from the first gate region; and
a fourth layer epitaxially grown laterally next to the second gate region on the first layer.

31. The arrangement as claimed in claim 25, further comprising:
a second gate region formed on an opposite side of the first layer from the first gate region; and
a raised source region and a raised drain region formed next to the first gate region and/or next to the second gate region.
